(19) United States
(12) Patent Application Publication
(10) Pub. No.: US 2023/0045014 A1
(43) Pub. Date: Feb. 9, 2023

(54) CUTTING APPARATUS

(71) Applicant: DISCO CORPORATION, Tokyo (JP)

(72) Inventors: Takashi FUKAZAWA, Tokyo (JP); Toshifumi MATSUYAMA, Tokyo (JP)

(21) Appl. No.: 17/816,852

(22) Filed: Aug. 2, 2022

(30) Foreign Application Priority Data
Aug. 3, 2021 (JP) 2021-127437

(51) Int. Cl. B26D 7/08; B28B 11/14; B26D 7/18

(52) U.S. Cl. CPC B26D 7/088; B28B 11/14; B26D 7/1863; B26D 7/1854

(57) ABSTRACT

A cutting unit of a cutting apparatus includes a fixed flange that is disposed at an end portion of a spindle to support a cutting blade and has a plurality of first gas jetting passages on a periphery thereof for jetting gas radially along a cutting edge of the cutting blade, a detachable flange that sandwiches the cutting blade in cooperation with the fixed flange and has a plurality of second gas jetting passages on a periphery thereof for jetting gas radially along the cutting edge of the cutting blade, a cover covering the cutting blade, the fixed flange, and the detachable flange, and a vacuum unit provided to the cover and configured to suck dust scattered inside the cover.

### BACKGROUND OF THE INVENTION

### Field of the Invention

The present invention relates to a cutting apparatus including a chuck table, a cutting unit rotatably having a cutting blade that cuts a workpiece held on the chuck table, and a processing-feed mechanism that processing-feeds the chuck table and the cutting unit relative to each other.

### Description of the Related Art

A wafer having a plurality of devices such as integrated circuits (ICs) or large scale integration (LSI) circuits formed on a top surface thereof in a manner being demarcated by a plurality of intersecting planned dividing lines is divided into individual device chips by a dicing apparatus. The divided device chips are used in electric appliances such as mobile telephones or personal computers.

A generally known dicing apparatus includes a chuck table that holds a workpiece, a cutting unit that cuts the workpiece held on the chuck table while supplying cutting water to the workpiece, and a processing-feed mechanism that processing-feeds the chuck table and the cutting unit relative to each other. The dicing apparatus can remove dust produced from a cut part and cool a cutting region with use of the cutting water, and divide the wafer held as the workpiece into individual device chips with high accuracy (see Japanese Patent Laid-Open No. 2010-050214, for example).

### SUMMARY OF THE INVENTION

Some wafers to be cut by the dicing apparatus have a top surface layer formed of a substance processibility of which could be lowered due to the cutting water, such as raw ceramic (ceramic before sintering), for example. The dicing apparatus that uses the cutting water as described above is unsuitable in cutting such a workpiece. In addition, processing heat caused by friction occurs when the workpiece is cut by the cutting blade. When cutting processing is performed without the use of the cutting water, it is not possible to cool the cutting blade and the workpiece while removing the dust appropriately, so that processing quality is decreased.

It is accordingly an object of the present invention to provide a cutting apparatus that can cool the cutting blade and the workpiece appropriately while removing dust scattered from the cut part, without the use of the cutting water.

In accordance with an aspect of the present invention, there is provided a cutting apparatus including a chuck table configured to hold a workpiece, a cutting unit having a cutting blade to cut the workpiece held on the chuck table, and a processing-feed mechanism configured to processing-feed the chuck table and the cutting unit relative to each other. The cutting unit includes a spindle, the cutting blade supported to an end portion of the spindle, a flange unit, a cover covering the cutting blade and the flange unit, and a vacuum unit provided to the cover and configured to suck dust scattered inside the cover. The flange unit includes a fixed flange that is fixed to an end portion of the spindle to support the cutting blade and has a plurality of first gas jetting passages on a periphery thereof for jetting gas radially along a cutting edge of the cutting blade, and a detachable flange that sandwiches the cutting blade in cooperation with the fixed flange and has a plurality of second gas jetting passages on a periphery thereof for jetting gas radially along the cutting edge of the cutting blade.

Preferably, the cover has a gas jetting nozzle for jetting gas to a region in which the cutting blade cuts the workpiece. Preferably, the gas is one of air, N₂, CO₂, and dry mist or a combination thereof.

According to the present invention, without the use of cutting water, dust scattered inside the cover is sucked from inside the cover, and the cutting edge of the cutting blade and the workpiece are cooled. Thus, even a workpiece made of a material processibility of which could be lowered due to cutting water can be cut while cooled appropriately, so that processing quality is maintained.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a general perspective view of a cutting apparatus according to an embodiment of the present invention;

FIG. 2A is a perspective view of a cutting unit disposed in the cutting apparatus illustrated in FIG. 1;

FIG. 2B is an exploded perspective view of the cutting unit illustrated in FIG. 2A;

FIG. 3A is an exploded perspective view of a configuration in which a cover is removed from the cutting unit illustrated in FIG. 2B;

FIG. 3B is a sectional view in which the cutting unit illustrated in FIG. 3A is sectioned along a disposition direction of a spindle;

FIG. 4A is a sectional view of a state in which the cutting unit of FIG. 3B is performing a cutting step;

and

FIG. 4B is a conceptual diagram illustrating, in section, a part of the cutting unit as viewed from a side.

### DETAILED DESCRIPTION OF THE PREFERRED EMBODIMENT

A cutting apparatus according to an embodiment of the present invention will hereinafter be described in detail with reference to the accompanying drawings.

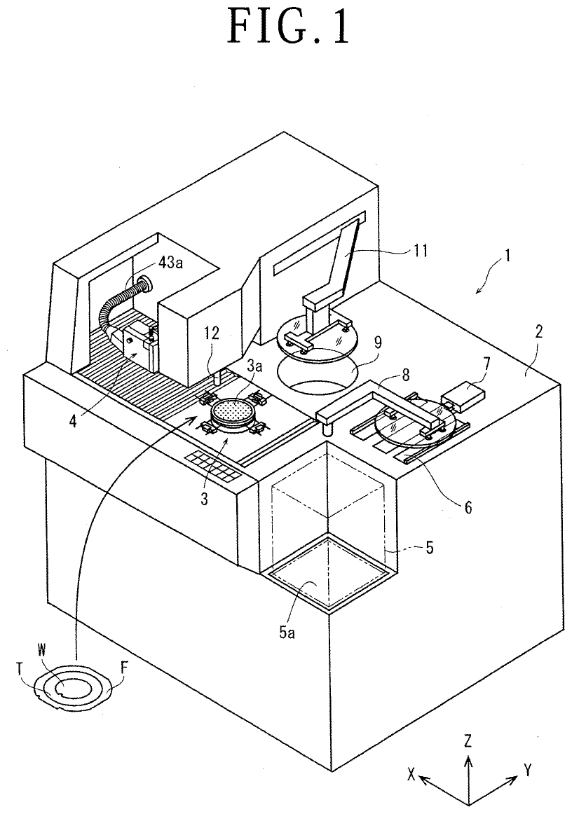

FIG. 1 illustrates a cutting apparatus 1 according to the present embodiment. The cutting apparatus 1 in the present embodiment has an apparatus housing 2 substantially in the shape of a rectangular parallelepiped. The cutting apparatus 1 includes a chuck table mechanism 3 disposed as a holding unit that holds a wafer W as a workpiece, and a cutting unit 4 rotatably having a cutting blade that cuts the wafer W held by the chuck table mechanism 3. Incidentally, the wafer W to be processed in the present embodiment is, for example, a wafer having a raw ceramic layer formed on a top surface thereof and is supported by an annular frame F via an adhesive tape T.

The cutting apparatus 1 includes a cassette 5 (indicated by a chain double-dashed line) that houses a plurality of wafers W as workpieces, a temporary placement table 6 on which a wafer W unloaded from the cassette 5 is temporarily placed, a loading and unloading mechanism 7 that unloads the wafer W from the cassette 5 onto the temporary placement table 6, a transporting mechanism 8 that turns to transport the wafer W unloaded onto the temporary placement table 6 onto a suction chuck 3a of the chuck table mechanism 3, cleaning means 9 (details thereof are omitted) for cleaning the wafer W cut by the cutting unit 4, a cleaning transporting mechanism 11 that transports the cut wafer W from the suction chuck 3a of the chuck table mechanism 3 to the cleaning means 9, an imaging unit 12 that images the wafer W on the suction chuck 3a, and a control unit not illustrated. The cassette 5 is mounted on a cassette table 5a disposed to be movable vertically by raising and lowering means not illustrated. The height of the cassette 5 is adjusted as appropriate when the loading and unloading mechanism 7 unloads a wafer W from the cassette 5.

Disposed inside the apparatus housing 2 is a processing-feed mechanism (not illustrated) that is means for processing-feeding the chuck table mechanism 3 and the cutting unit 4 relative to each other and which moves the chuck table mechanism 3 in an X-axis direction indicated by an arrow X as a cutting-feed direction.

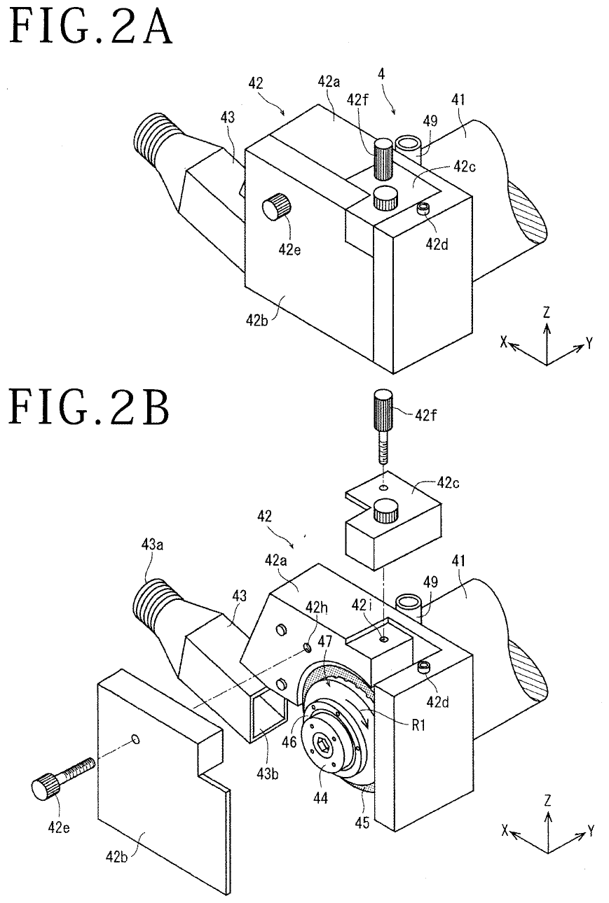

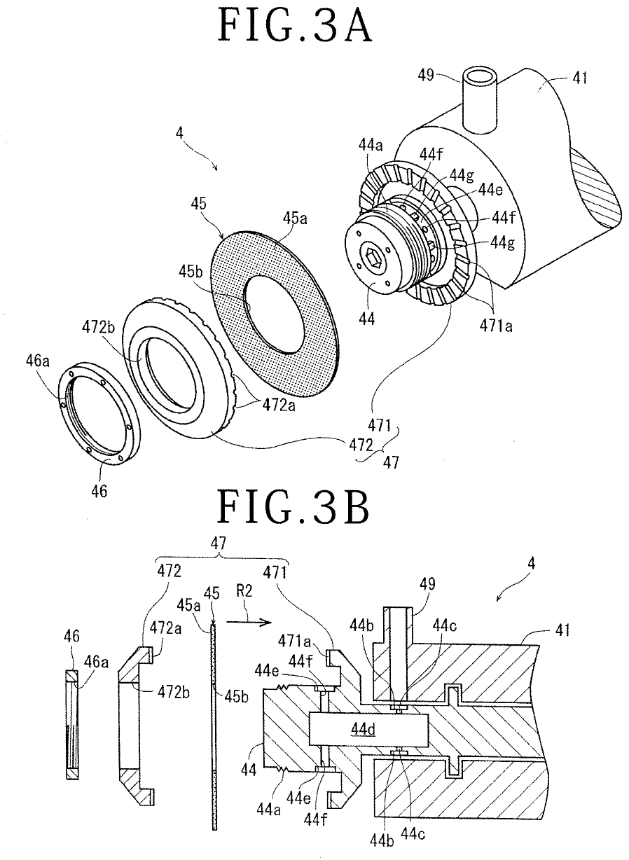

The above-described cutting unit 4 will be described more specifically with reference to FIGS. 2A to 3B. FIG. 2A illustrates main parts of the cutting unit 4 on an enlarged scale. FIG. 2B illustrates a perspective view in which a part of the cutting unit 4 illustrated in FIG. 2A is disassembled. In addition, FIG. 3A illustrates a state in which the cutting unit 4 illustrated in FIG. 2A and FIG. 2B is further disassembled with a cover 42 of the cutting unit 4 omitted for the convenience of description. FIG. 3B illustrates a sectional view in which the cutting unit 4 illustrated in FIG. 3A is sectioned along a disposition direction of a spindle 44.

As is understood from FIG. 2A and FIG. 2B, the cutting unit 4 includes a spindle housing 41 extending in a Y-axis direction indicated by an arrow Y, the spindle 44 rotatably supported by the spindle housing 41, an annular cutting blade 45 detachably supported to an end portion of the spindle 44, the cover 42 that is fitted to an end of the spindle housing 41 and covers the cutting blade 45 and a flange unit 47 to be described later, a vacuum unit 43 that is provided to the cover 42 and sucks dust scattered inside the cover 42, and a nut 46 for fixing the cutting blade 45 to a distal end portion of the spindle 44 in cooperation with the flange unit 47. Incidentally, the spindle 44 is rotationally driven in a direction indicated by an arrow R1 by an electric motor not illustrated. In addition, the cutting unit 4 is provided with a moving mechanism not illustrated. The moving mechanism includes an indexing-feed mechanism that indexing-feeds the cutting unit 4 in the Y-axis direction indicated by the arrow Y, and a cutting-feed mechanism that is capable of moving the cutting unit 4 in a Z-axis direction (upward-downward direction) indicated by an arrow Z and cutting-feeds the cutting unit 4 by moving the cutting unit 4 downward.

As illustrated in FIG. 2B, the cover 42 includes a first cover member 42a fixed to the spindle housing 41, a second cover member 42b fixed to the first cover member 42a by a screw 42e being screwed into a threaded hole 42h defined in a front surface of the first cover member 42a, and a blade detecting block 42c fixed to the first cover member 42a by a screw 42f being screwed into a threaded hole 42i defined in an upper surface of the first cover member 42a from above. In the blade detecting block 42c, a blade sensor (not illustrated) is disposed for detecting wear or chipping in a cutting edge 45a part on a peripheral edge portion side of the cutting blade 45. The vacuum unit 43 is provided to the cover 42. The vacuum unit 43 is disposed in a direction in which dust including cutting waste is scattered inside the cover 42 housing the cutting blade 45 when the cutting blade 45 is rotated in the direction indicated by the arrow R1 in FIG. 2B, for example. The vacuum unit 43 sucks the dust and discharges the dust to the outside. The dust is then captured by a filter not illustrated or the like. The vacuum unit 43 has a discharge port 43a formed by a flexible hose connected to suction means not illustrated and a suction port 43b that opens to the inside of the cover 42 and sucks the dust.

As is understood from FIG. 3A, the flange unit 47 is disposed at an end portion of the spindle 44. The flange unit 47 includes a fixed flange 471 and a detachable flange 472. The fixed flange 471 is fixed to the end portion of the spindle 44 to support the cutting blade 45, and has a plurality of gas jetting passages 471a for jetting gas radially along the cutting edge 45a constituting the peripheral side of the cutting blade 45. The detachable flange 472 is configured to be detachable from the spindle 44 and sandwiches the cutting blade 45 in cooperation with the fixed flange 471. The detachable flange 472 has, on a periphery thereof, a plurality of jetting passages 472a for jetting gas radially along the cutting edge 45a constituting the peripheral side of the cutting blade 45. Incidentally, while FIG. 3A does not illustrate the whole of the jetting passages 472a provided to the detachable flange 472, the jetting passages 472a are formed in a manner similar to the jetting passages 471a of the fixed flange 471 disposed to face the detachable flange 472.

At the end portion of the spindle 44, a male thread 44a is formed on a peripheral surface on a further distal end side with respect to the fixed flange 471. In addition, as illustrated in FIG. 3A and FIG. 3B, a gas introducing port 49 is formed in the spindle housing 41. The gas introducing port 49 is connected to gas supply means not illustrated. Gas at a high pressure (for example, 0.3 to 0.5 MPa) is introduced from the gas supply means via the gas introducing port 49 into the spindle housing 41. Incidentally, the gas introduced via the gas introducing port 49 is preferably one of air, nitrogen (N₂), carbon dioxide (CO₂), and dry mist or a combination thereof. As illustrated in FIG. 3B, an annular groove 44b is formed at a position facing the gas introducing port 49 in the peripheral surface of the spindle 44 rotatably supported by the spindle housing 41. A communication passage 44d formed along a longitudinal direction of the spindle 44 is formed inside the spindle 44. A plurality of holes 44c formed in the annular groove 44b are connected to the communication passage 44d.

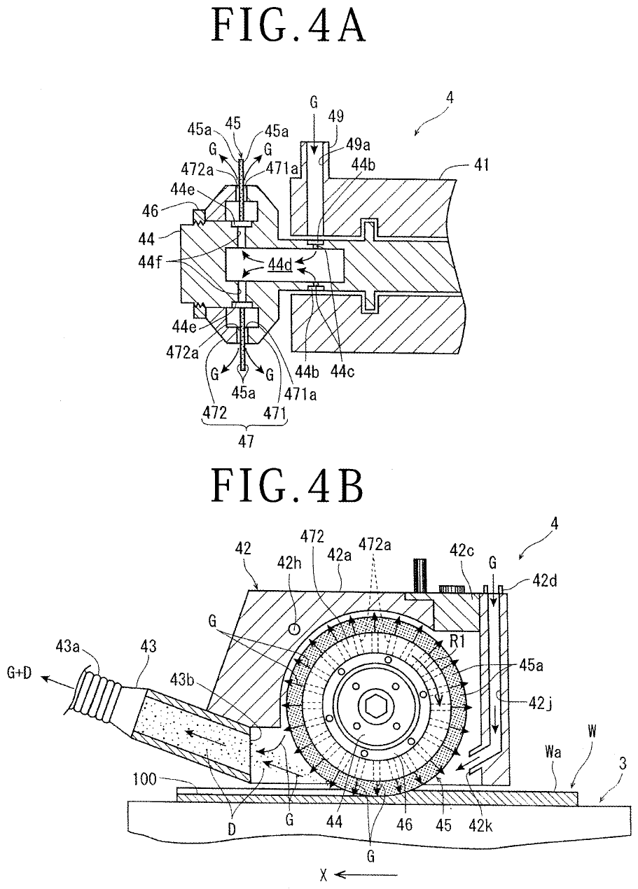

In addition, at the end portion of the spindle 44, an annular groove 44e is formed in the peripheral surface between the fixed flange 471 and the male thread 44a. A plurality of holes 44f, for example, six holes 44f, which make the above-described communication passage 44d and the annular groove 44e communicate with each other, are formed at equal intervals in a bottom portion of the annular groove 44e. In addition, as illustrated in FIG. 3A, on the bottom portion of the annular groove 44e, a protruding portion 44g having a height corresponding to the depth of the annular groove 44e is formed at an intermediate position between adjacent holes 44f. The protruding portion 44g is formed at a plurality of positions at equal intervals in the annular groove 44e. In the present embodiment, the number of protruding portions 44g is the same (six) as the number of holes 44f. As illustrated in FIG. 3B, the cutting blade 45 is positioned on the annular groove 44e (see also FIG. 4A) by positioning an opening portion 45b of the cutting blade 45 from the distal end side (left side in the figure) of the spindle 44 to fit the cutting blade 45 in a direction indicated by an arrow R2 and causing the cutting blade 45 to abut against the fixed flange 471, to thereby fix the cutting blade 45 to the end portion of the spindle 44. At this time, the opening portion 45b of the cutting blade 45 abuts against and is supported by the above-described protruding portions 44g. Further, an opening portion 472b of the detachable flange 472 is positioned at and fitted to the distal end side of the spindle 44, and a female thread 46a of the nut 46 is screwed and fastened to the male thread 44a of the spindle 44. The cutting blade 45 is thus sandwiched and fixed by the surface of the fixed flange 471 having the jetting passages 471a formed thereon and the surface of the detachable flange 472 having the jetting passages 472a formed thereon.

In the cutting unit 4 configured as described above, as illustrated in FIG. 4A, when high pressure gas G is supplied via the gas introducing port 49 of the spindle housing 41, the gas G is routed through the annular groove 44b, the holes 44c, the communication passage 44d, the holes 44f, and the annular groove 44e of the spindle 44 and is introduced into the jetting passages 471a of the fixed flange 471 and the jetting passages 472a of the detachable flange 472. Thus, the gas G can be jetted radially along the cutting edge 45a of the cutting blade 45.

The cutting apparatus 1 according to the present embodiment generally has the configuration as described above. Actions and effects of the cutting apparatus 1 will be described in the following.

In the cutting apparatus 1 described with reference to FIG. 1, when a cutting step of cutting the wafer W described above is to be performed, a wafer W unloaded from the cassette 5 is transported and placed onto the suction chuck 3a of the chuck table mechanism 3 and is held under suction by the suction chuck 3a. After the wafer W is held under suction by the suction chuck 3a, the chuck table mechanism 3 is positioned directly below the above-described imaging unit 12 by actuating the above-described processing-feed mechanism, the wafer W is imaged, and an alignment step is performed. Next, on the basis of positional information of a position to be processed on the wafer W, for example, a planned dividing line (not illustrated), which is detected in the alignment step, the wafer W is positioned directly below the cutting unit 4 by moving the chuck table mechanism 3.

After the wafer W is positioned directly below the cutting unit 4, a predetermined planned dividing line extending in a first direction of the wafer W is matched to the X-axis direction, and alignment between the predetermined planned dividing line and the above-described cutting blade 45 is performed. Next, as illustrated in FIG. 4B, the cutting blade 45 being rotated at high speed in a direction indicated by an arrow R1 is positioned at the planned dividing line matched to the X-axis direction, the cutting blade 45 is made to cut into the wafer W by a predetermined depth from a top surface Wa side, and the chuck table mechanism 3 is moved in a direction indicated by an arrow X. A cut groove 100 is thus formed. At this time, the gas G introduced from the gas introducing port 49 illustrated in FIG. 4A is introduced via the communication passage 44d inside the spindle 44, is guided to the jetting passages 471a formed on the fixed flange 471 and the jetting passages 472a formed on the detachable flange 472, and is jetted radially along the cutting edge 45a of the cutting blade 45 as illustrated in FIG. 4B. The gas G jetted radially along the cutting edge 45a of the cutting blade 45 is sucked from the suction port 43b of the vacuum unit 43 and discharged from the discharge port 43a to the outside, together with dust D including cutting waste produced by cutting. The dust D discharged from the discharge port 43a is captured by a filter not illustrated or the like.

After the cut groove 100 is formed as described above, the cutting blade 45 of the cutting unit 4 is indexing-fed to another planned dividing line which extends in the first direction, which is adjacent to the cut groove 100, and in which no cut groove 100 is formed. Then, cutting processing that forms a cut groove 100 is performed in a manner similar to the above. Cut grooves 100 are formed along all of the planned dividing lines extending in the first direction by repeating the above processing. Next, the wafer W is rotated by 90 degrees together with the chuck table mechanism 3, a planned dividing line extending in a second direction orthogonal to the first direction in which the cut grooves 100 have been formed is matched to the X-axis direction, and the above-described cutting processing is performed for all of the planned dividing lines newly matched to the X-axis direction. Cut grooves 100 are thus formed along all of the planned dividing lines formed on the wafer W (cutting step).

With the cutting apparatus according to the present embodiment, a dry type system not using cutting water can suck the dust D scattered inside the cover 42 from the inside of the cover 42 by the vacuum unit 43 together with the above-described gas G and cool the cutting edge 45a of the cutting blade 45 and the wafer W as a workpiece. Thus, even a workpiece made of a material processibility of which could be lowered due to cutting water as described above can be cut appropriately, so that processing quality is maintained.

Further, as illustrated in FIG. 4B, the cover 42 of the cutting unit 4 of the cutting apparatus 1 according to the present embodiment is provided with a gas jetting nozzle 42k that jets gas G to a region in which the cutting blade 45 is cutting the wafer W. More specifically, the gas jetting nozzle 42k is disposed at a position opposed to the vacuum unit 43 with the cutting blade 45 interposed therebetween, is made to communicate with a gas introduction passage 42j formed inside the first cover member 42a and with a gas introducing port 42d (see also FIG. 2A and FIG. 2B) defined in the upper surface of the first cover member 42a, and is connected to gas supply means not illustrated. When the gas G supplied from the gas supply means is jetted from the gas jetting nozzle 42k, the dust D produced when the cutting step is performed is guided to and sucked by the vacuum unit 43 more efficiently, and the cutting edge 45a of the cutting blade 45 and the wafer W as a workpiece are cooled more efficiently.

Incidentally, in the foregoing embodiment, the same gas G as the above-described gas G introduced from the gas introducing port 49 formed in the spindle housing 41 is selected as the gas G introduced from the gas introducing port 42d formed in the upper surface of the first cover member 42a. However, the present invention is not limited to this, and different kinds of gas may be selected. For example, a dry mist may be selected as the gas G to be introduced from the gas introducing port 49 formed in the spindle housing 41, and jetted radially along the cutting edge 45a of the cutting blade 45, while nitrogen (N₂) may be selected as the gas G to be jetted from the gas jetting nozzle 42k, and jetted to the region in which the cutting blade 45 is cutting the wafer W.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A cutting apparatus comprising:
a chuck table configured to hold a workpiece;
a cutting unit having a cutting blade to cut the workpiece held on the chuck table; and
a processing-feed mechanism configured to processing-feed the chuck table and the cutting unit relative to each other;
the cutting unit including
a spindle,
the cutting blade supported to an end portion of the spindle,
a flange unit including a fixed flange that is fixed to an end portion of the spindle to support the cutting blade and has a plurality of first gas jetting passages on a periphery thereof for jetting gas radially along a cutting edge of the cutting blade, and a detachable flange that sandwiches the cutting blade in cooperation with the fixed flange and has a plurality of second gas jetting passages on a periphery thereof for jetting gas radially along the cutting edge of the cutting blade,
a cover covering the cutting blade and the flange unit, and
a vacuum unit provided to the cover and configured to suck dust scattered inside the cover.

2. The cutting apparatus according to claim 1, wherein
the cover has a gas jetting nozzle for jetting gas to a region in which the cutting blade cuts the workpiece.

3. The cutting apparatus according to claim 1, wherein
the gas is one of air, N₂, CO₂, and dry mist or a combination thereof.
